(19) United States
(12) Patent Application Publication
(10) Pub. No.: US 2019/0357335 A1
(43) Pub. Date: Nov. 21, 2019

(54) DISPLAY DEVICE, MANUFACTURING APPARATUS, AND DEFECT CORRECTION APPARATUS

(71) Applicant: Sharp Kabushiki Kaisha, Sakai City, Osaka (JP)

(72) Inventor: Yoshitomo TSUCHI, Sakai City (JP)

(21) Appl. No.: 16/462,271

(22) PCT Filed: May 24, 2017
(86) PCT No.: PCT/JP2017/019360

§ 371 Date: May 20, 2019

(51) Int. Cl. H05B 33/10; H05B 33/04; H05B 33/06; H01L 51/50

(52) U.S. Cl. CPC H05B 33/10; H05B 33/04; G09F 9/30; H01L 51/5012; H05B 33/06

(57) ABSTRACT

In a display device, a defective subpixel has one region being a non light-emitting region conforming to the planar shape of conductive foreign matter and the other region being a light-emitting region. The display device includes a cathode electrode provided commonly to a plurality of red pixels, green pixels, and blue pixels. In the defective subpixel, the cathode electrode has a light emission corresponding portion and a non light emission corresponding portion that are not electrically connected with each other.

### TECHNICAL FIELD

The disclosure relates to the correction of a defect in a subpixel included in a display device.

### BACKGROUND ART

PTL 1 discloses an organic electroluminescence (EL) display panel correction facility (hereinafter referred to as a correction facility) that radiates laser light to correct a defect in a pixel formed of an organic EL element. On the basis of the position and size of foreign matter contained in the pixel, this correction facility radiates the laser light toward the position of the foreign matter through a photomask having an optically transparent pattern that transmits the laser light.

### CITATION LIST

### Patent Literature

PTL 1: JP 2011-134490 A (published on Jul. 7, 2011)

### SUMMARY

### Technical Problem

Unfortunately, the correction facility of PTL 1 selects a photomask to be used among a plurality of prepared photomasks in accordance with the size of the foreign matter. Thus, depending on the shape or size of a defect, that is, a case of elongated foreign matter, a case of foreign matter extending over adjacent pixels, or the like, the prepared photomasks may not be suitable for the foreign matter, so that the defect in the pixel may not be corrected as intended.

An object of one aspect of the disclosure is to achieve a display device in which a defect in a subpixel is precisely corrected, a defect correction apparatus capable of precisely correcting the defect, or the like.

### Solution to Problem

To solve the above problem, a display device according to one aspect of the disclosure is a display device including a plurality of subpixels configured to emit light of mutually different colors. The plurality of subpixels include at least one defective subpixel containing foreign matter. The at least one defective subpixel includes: one region including a non light-emitting region conforming to a planar shape of the foreign matter, and the other region including a light-emitting region. Each of the plurality of subpixels includes a substrate; and a first electrode, a light-emitting layer, and a second electrode in this order on the substrate. The second electrode is provided commonly to the plurality of subpixels. In the at least one defective subpixel, a portion, corresponding to the light-emitting region, of the second electrode is not electrically connected with a portion, corresponding to the non light-emitting region, of the second electrode.

Furthermore, to solve the above problem, a defect correction apparatus according to one aspect of the disclosure is a defect correction apparatus configured to correct a defect occurring in at least any one of a plurality of subpixels included in a display device, the plurality of subpixels being configured to emit light of mutually different colors. The defect correction apparatus includes: a laser light radiation unit configured to radiate laser light along an outer periphery of a region containing foreign matter in the at least any one of the plurality of subpixels containing the foreign matter in conformance to a shape of the foreign matter contained in the at least any one of the plurality of subpixels, without using a prescribed pattern determined preliminarily.

Furthermore, to solve the above problem, a defect correction method of one aspect of the disclosure is a defect correction method correcting a defect occurring in at least any one of a plurality of subpixels included in a display device, the plurality of subpixels being configured to emit light of mutually different colors. The defect correction method includes: radiating laser light along an outer periphery of a region containing foreign matter in the at least any one of the plurality of subpixels containing the foreign matter in conformance to a shape of the foreign matter contained in the at least any one of the plurality of subpixels, without using a prescribed pattern determined preliminarily.

### Advantageous Effects of Disclosure

According to a display device of one aspect of the disclosure, a display device in which a defect in a subpixel is precisely corrected can be provided.

Furthermore, a defect correction apparatus and a defect correction method according to one aspect of the disclosure achieve an effect of precisely correcting a defect in a subpixel.

### BRIEF DESCRIPTION OF DRAWINGS

FIG. 1 is a flowchart illustrating an example of a manufacturing method of a display device.

FIG. 2A is a cross-sectional view illustrating a configuration (a state in which a layered body is formed on a substrate) of a display device during formation, and FIG. 2B is a cross-sectional view illustrating a configuration example of a display device.

FIG. 3 is a plan view illustrating the configuration (the state in which a layered body is formed on a substrate) of a display device during formation.

FIG. 4 is a block diagram illustrating a configuration example of a manufacturing apparatus according to a first embodiment.

FIG. 5 is a schematic diagram illustrating a configuration example of a defect correction apparatus according to the first embodiment.

FIGS. 6A to 6D are diagrams for describing a defect correction method according to the first embodiment. FIG. 6A is a schematic diagram illustrating a state in which conductive foreign matter contaminates a red pixel, FIG. 6B is a diagram illustrating an example of the determination of a cutoff line position being a laser light irradiation position, FIG. 6C is a diagram illustrating light-emitting states of the red pixel, a green pixel, and a blue pixel, and FIG. 6D is a diagram illustrating a cathode electrode after irradiation with laser light.

FIG. 7 is a flowchart illustrating an example procedure at a defect correction apparatus according to the first embodiment.

FIGS. 8A to 8C are diagrams for describing a defect correction method according to a second embodiment. FIG. 8A is a diagram schematically illustrating a state in which conductive foreign matter contaminates a plurality of subpixels and illustrating an example of the determination of a cutoff line position being a laser light irradiation position, FIG. 8B is a diagram illustrating light-emitting states of a red pixel, a green pixel, and a blue pixel, and FIG. 8C is a diagram illustrating a cathode electrode after irradiation with laser light.

FIGS. 9A and 9B are diagrams for describing a defect correction method according to a third embodiment. FIG. 9A is a diagram schematically illustrating a state in which conductive foreign matter contaminates a plurality of subpixels and illustrating an example of the determination of a cutoff line position being a laser light irradiation position, and FIG. 9B is a diagram illustrating a cathode electrode after irradiation with laser light.

FIGS. 10A to 10C are diagrams for describing defect correction methods according to a fourth embodiment. FIG. 10A is a diagram illustrating a defect correction method for subpixels having the same size when the display device is viewed from above, FIG. 10B is a diagram illustrating a defect correction method for subpixels having different sizes, and FIG. 10C is a diagram for describing a defect correction method, differing from that in FIG. 10A, for subpixels having the same size.

### DESCRIPTION OF EMBODIMENTS

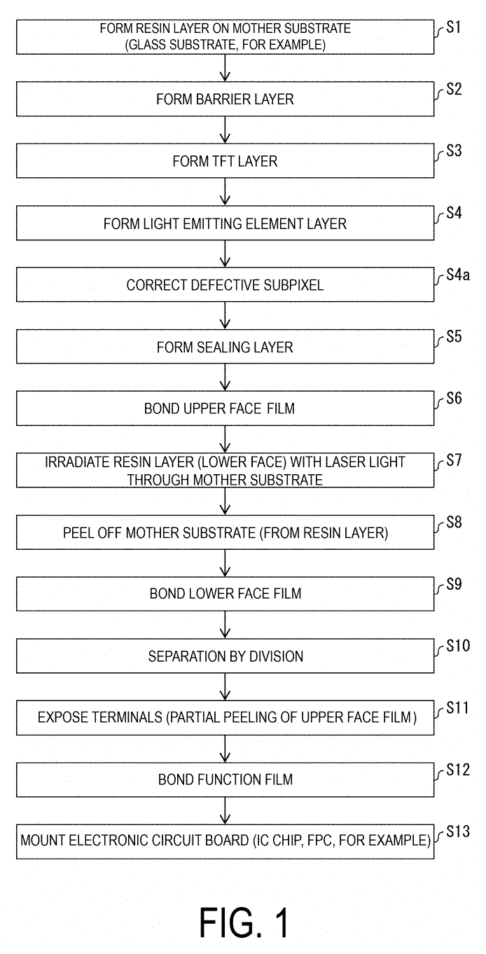

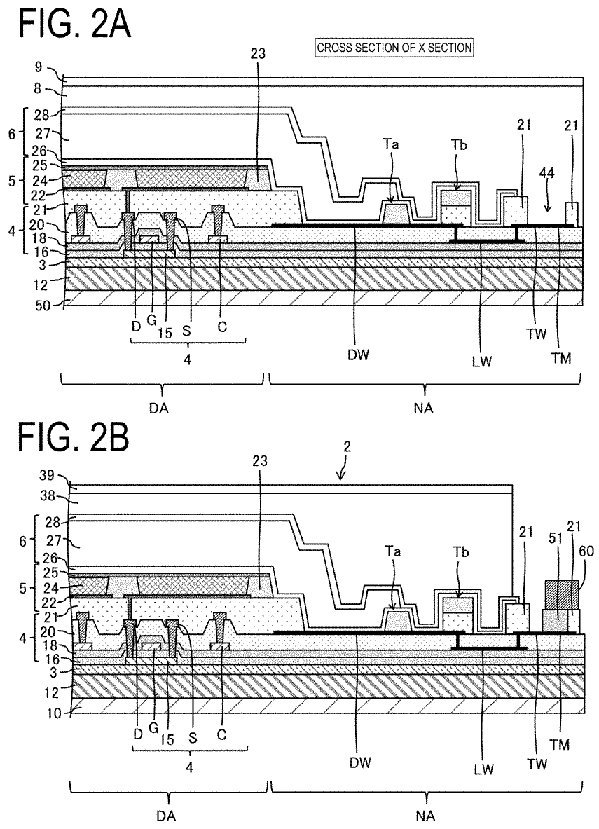

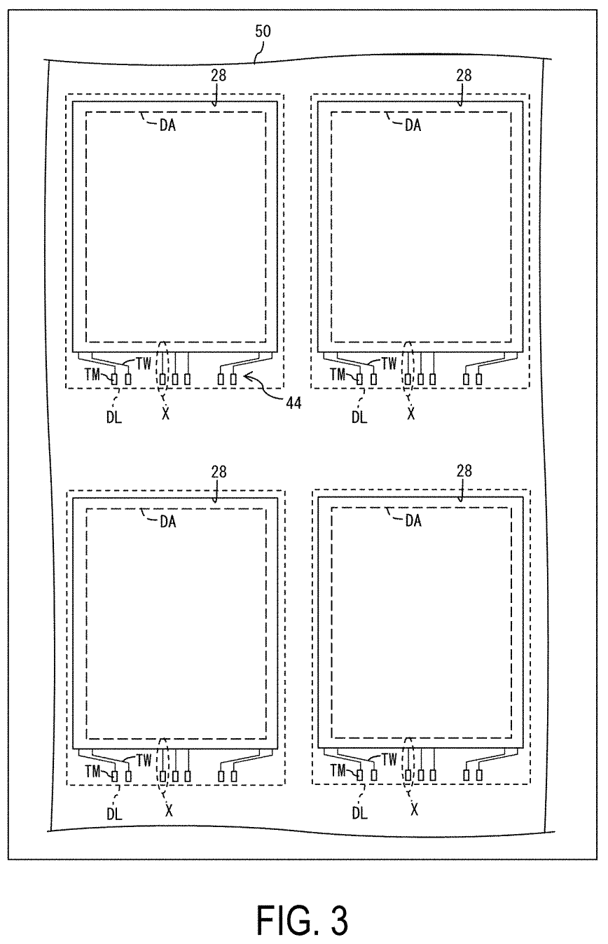

FIG. 1 is a flowchart illustrating an example of a display device manufacturing method. FIG. 2A is a cross-sectional view illustrating a configuration (a state in which a layered body is formed on a substrate) of the display device during formation, and FIG. 2B is a cross-sectional view illustrating a configuration example of the display device. FIG. 3 is a plan view illustrating the configuration (the state in which the layered body is formed on the substrate) of the display device during formation.

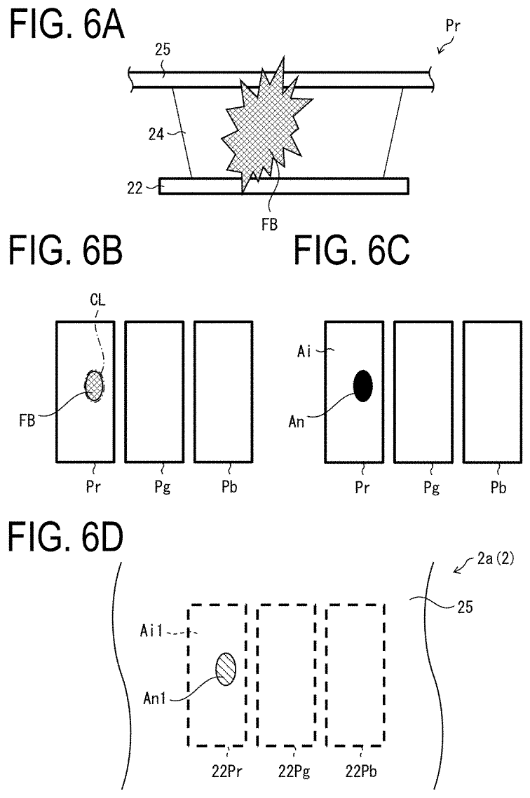

When a flexible display device (a display device having flexibility) is manufactured, as illustrated in FIG. 1, FIG. 2A and FIG. 3, first, a resin layer 12 is formed on a transparent substrate 50 (a mother glass, for example) (step S1). Next, a barrier layer (an inorganic barrier film) 3 is formed (step S2). Next, a TFT layer 4 is formed (step S3). Next, a light emitting element layer (for example, an OLED element layer) 5 is formed (Step S4). Next, it is determined whether a subpixel (defective subpixel) containing conductive foreign matter FB exists in a light-emitting element layer 5 (see FIGS. 6A and 6B). In a case where such a defective subpixel exists, the defective subpixel is corrected (step S4a). In other words, in step S4a, a defect occurring in at least any of a plurality of subpixels is corrected. Next, a sealing layer 6 is formed (step S5). Next, an upper face film 9 (a PET film, for example) is bonded to the sealing layer 6, with an adhesive layer 8 interposed therebetween (step S6).

Next, a lower face of the resin layer 12 is irradiated with a laser light through the substrate 50 (step S7). Here, the resin layer 12 absorbs the laser light with which the lower face of the substrate 50 has been irradiated and that has passed through the substrate 50, and as a result, the lower face of the resin layer 12 (an interface with the substrate 50) alters due to ablation, and bonding force between the resin layer 12 and the substrate 50 weakens. Next, the substrate 50 is peeled from the resin layer 12 (step S8). Next, as illustrated in FIG. 2B, a lower face film 10 (a PET film, for example) is bonded to the lower face of the resin layer 12, with an adhesive layer interposed therebetween (step S9). Then, a layered body including the lower film 10, the resin layer 12, the barrier layer 3, the TFT layer 4, the light emitting element layer 5, the sealing layer 6, and the upper face film 9 is divided along cutting lines DL illustrated in FIG. 3, and at the same time, the upper face film 9 is cut and a plurality of individual pieces are cut out (step S10). Next, terminal exposure is performed by peeling a part (a section on a terminal portion 44) of the upper face film 9 off the individual piece (step S11). Next, a function film 39 is bonded to the upper side of the sealing layer 6 of the individual piece, with an adhesive layer 38 interposed therebetween (step S12). Then, an electronic circuit board 60 is mounted onto the terminal portion 44 of the individual piece, with an anisotropic conductive material 51 interposed therebetween (step S13). In this way, a display device 2 illustrated in FIG. 2B is obtained. Note that each of the above-described steps is performed by a display device manufacturing apparatus.

Examples of the material of the resin layer 12 include polymide, epoxy, and polyamide. Examples of the material used in the lower face film 10 include polyethylene terephthalate (PET).

The barrier layer 3 is a layer that inhibits moisture or impurities from reaching the TFT layer 4 or the light emitting element layer 5 when the display device 2 is being used, and can be composed of a silicon oxide film, a silicon nitride film, or a silicon oxynitride film, or of a layered film of these, formed using CVD.

The TFT layer 4 includes a semiconductor film 15, an inorganic insulating film 16 (a gate insulating film) formed on the semiconductor layer 15, a gate electrode G formed on the inorganic insulating film 16, an inorganic insulating film 18 formed on the gate electrode G, a capacitance wiring line C formed on the inorganic insulating film 18, an inorganic insulating film 20 formed on the capacitance wiring line C, a source electrode S and a drain electrode D formed on the inorganic insulating film 20, and a flattening film 21 formed on the source electrode S and the drain electrode D.

A thin film transistor (TFT) is configured to include the semiconductor film 15, the inorganic insulating film 16, and the gate electrode G. The source electrode S is connected to a source region of the semiconductor film 15, and the drain electrode D is connected to a drain region of the semiconductor film 15.

The semiconductor film 15 is formed of, for example, low temperature polysilicon (LTPS) or an oxide semiconductor. The inorganic insulating film 16 can be formed by CVD, for example, and can be configured by a silicon oxide (SiOx) film, a silicon nitride (SiNx) film, or by a layered film of these films. The gate electrode G, the source electrode (source wiring line) S, the drain electrode (drain wiring line) D, and the terminals, for example, are configured by a single layer of a metal including at least one of aluminum (Al), tungsten (W), molybdenum (Mo), tantalum (Ta), chromium (Cr), titanium (Ti), or copper (Cu), or a layered film of these. Note that, in FIGS. 2A and 2B, the TFT is illustrated that has a top gate structure in which the semiconductor film 15 is the channel, but the TFT may have a bottom gate structure (when the TFT channel is the oxide semiconductor, for example).

The inorganic insulating films 18 and 20 can be composed of a silicon oxide (SiOx) film or a silicon nitride (SiNx) film, or a layered film of these, formed using CVD. The flattening film (interlayer insulating film) 21 can be composed, for example, of a coatable photosensitive organic material, such as a polyimide or an acrylic.

The terminal portion 44 is provided on an end portion (a non-active region NA) of the TFT layer 4. The terminal portion 44 includes a terminal TM that is used for connection with an IC chip or the electronic circuit board 60 such as a flexible printed circuit board (FPC); and a terminal wiring line TW connected to the terminal TM. The terminal wiring line TW is electrically connected to various wiring lines of the TFT layer 4 with a relay wire line LW and a lead-out wiring line DW therebetween.

The terminal TM, the terminal wiring line TW, and the lead-out wiring line DW are formed in the same process as that of the source electrode S, for example, and thus, are formed on the same layer (on the inorganic insulating film 20) and of the same materials (two layers of titanium film and an aluminum film sandwiched between the two layers of titanium film, for example) as those of the source electrode S. The relay wiring line LW is formed in the same process as that of the capacitance electrode C, for example. End faces (edges) of the terminal TM, the terminal wiring line TW, and the lead-out wiring line DW are covered by the flattening film 21.

The light-emitting element layer 5 (an organic light emitting diode layer, for example) includes an anode electrode 22 (first electrode) formed on the flattening film 21, a bank (pixel partition) 23 that defines a subpixel in an active region DA, an EL layer 24 (light-emitting layer) formed on the anode electrode 22, and a cathode electrode 25 (second electrode) formed on the EL layer 24; and a light emitting element (an Organic Light Emitting Diode (OLED), for example) is configured by the anode electrode 22, the EL layer 24, and the cathode electrode 25.

The EL layer 24 is formed in a region (a subpixel region) surrounded by the bank 23, by vapor deposition or an ink-jet method. In a case that the light emitting element layer 5 is an organic light emitting diode (OLED) layer, for example, the EL layer 24 is formed by layering a hole injecting layer, a hole transport layer, a light emitting layer, an electron transport layer, and an electron injecting layer from the lower layer side.

The anode electrode (anode electrode) 22 is formed by layering Indium Tin Oxide (ITO) and an alloy containing Ag, for example, and has light reflectivity (to be described below in more detail). The cathode electrode 25 can be composed of a light-transmissive conductive material such as Indium Tin Oxide (ITO) and Indium Zinc Oxide (IZO).

In a case that the light emitting element layer 5 is the OLED layer, positive holes and electrons are recombined inside the EL layer 24 by a drive current between the anode electrode 22 and the cathode electrode 25, and light is emitted as a result of excitons that are generated by the recombination falling into a ground state. Since the cathode electrode 25 is light-transmissive and the anode electrode 22 is light-reflective, the light emitted from the EL layer 24 travels upwards and results in top emission.

The light emitting element layer 5 is not limited to OLED element configurations, and may be an inorganic light emitting diode or a quantum dot light emitting diode.

Note that the anode electrode 22, the EL layer 24, and the cathode electrode 25 in the above-described subpixel region form one subpixel (e.g., each of a red pixel Pr, a green pixel Pg, and a blue pixel Pb illustrated in FIG. 6B). A set of one red pixel Pr, one green pixel Pg, and one blue pixel Pb forms one pixel. In other words, subpixels emitting light of different colors form a pixel. In addition, as illustrated in FIGS. 2A and 2B, the cathode electrode 25 is provided commonly to a plurality of subpixels.

A bulging body Ta and a bulging body Tb that define edges of an organic sealing film 27 are formed in the non-active region NA. The bulging body Ta functions as a liquid stopper when the organic sealing film 27 is applied using an ink-jet method, and the bulging body Tb functions as a backup liquid stopper. Note that a lower portion of the bulging body Tb is configured by the flattening film 21, and functions as a protection film for an end face of the lead-out wiring line DW. The bank 23, the bulging body Ta, and an upper portion of the bulging body Tb can be formed in the same process, for example, by using a coatable photosensitive organic material such as a polyimide, an epoxy, or an acrylic.

The sealing layer 6 is light-transmissive and includes a first inorganic sealing film 26 that covers the cathode electrode 25, the organic sealing film 27 that is formed on the first inorganic sealing film 26, and a second inorganic sealing film 28 that covers the organic sealing film 27.

The first inorganic sealing film 26 and the second inorganic sealing film 28 can be each composed of a silicon oxide film, a silicon nitride film, or a silicon oxinitride film, or by a layered film of these, formed using CVD. The organic sealing film 27 is thicker than the first inorganic sealing film 26 and the second inorganic sealing film 28, is a light-transmissive organic film, and can be composed of a coatable photosensitive organic material such as a polyimide or an acrylic. For example, after coating the first inorganic sealing film 26 with an ink containing such an organic material using the ink-jet method, the ink is cured by UV irradiation. The sealing layer 6 covers the light emitting element layer 5 and inhibits foreign matter, such as water and oxygen, from infiltrating to the light emitting element layer 5.

Note that the upper face film 9 is bonded onto the sealing layer 6 with the adhesive layer 8 interposed therebetween, and also functions as a support when the substrate 50 is peeled off. Examples of a material of the upper face film 9 include polyethylene terephthalate (PET).

The lower face film 10 is formed of PET or the like, and, by being bonded to the lower face of the resin layer 12 after the substrate 50 has been peeled off, functions as a support member and a protection member.

The function film 39 includes, for example, an optical compensation function, a touch sensor function, or a protection function. The electronic circuit board 60 is the IC chip or the flexible printed circuit board that is mounted on the plurality of terminals TM, for example. Note that the IC chip may be the IC chip with a bump.

A case of manufacturing the display device has been described above. When a non-flexible display device is to be manufactured, the peeling of the substrate and the like are not required, so that the process may advance from step S6 to step S10 illustrated in FIG. 1, for example.

Note that the display device is not particularly limited to a specific device as long as the display panel includes an optical element. The optical element is an optical element whose luminance and transmittance are controlled by an electric current, and examples of the electric current-controlled optical element include an organic EL display provided with an OLED, an EL display such as an inorganic EL display provided with an inorganic light emitting diode, or a Quantum Dot Light Emitting Diode (QLED) display provided with a QLED.

### First Embodiment

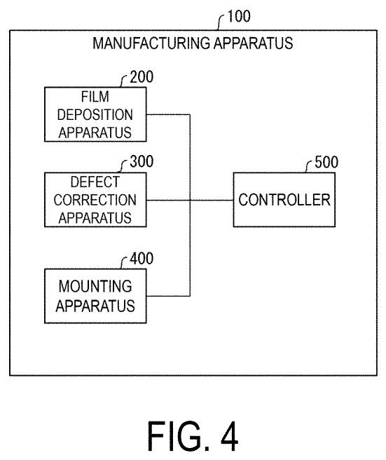

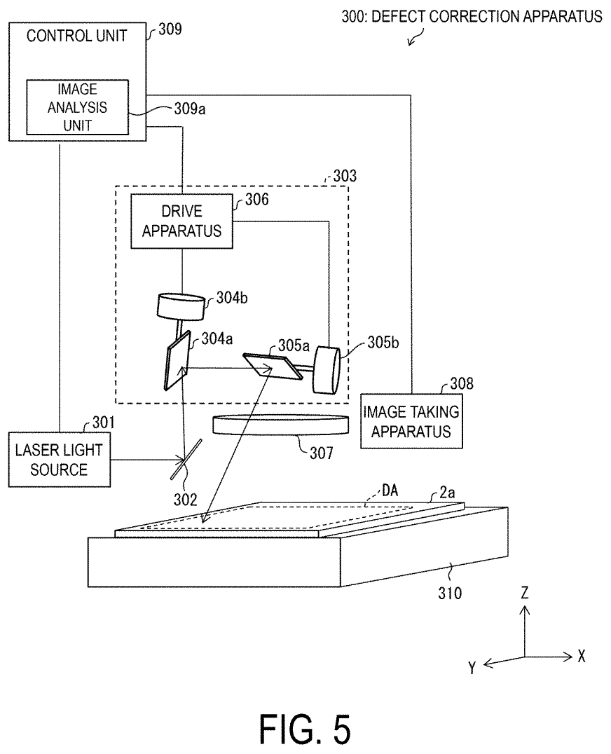

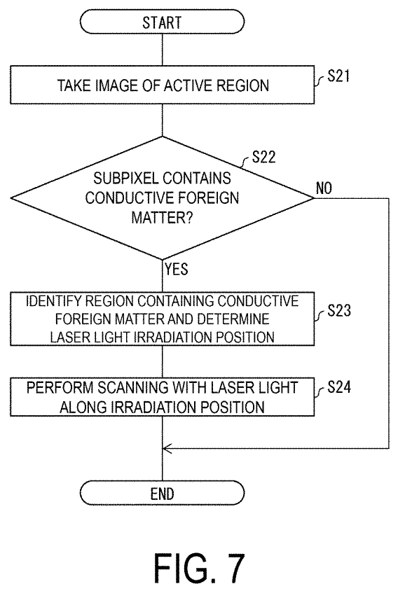

A configuration of a manufacturing apparatus 100 for the display device 2, and in particular a configuration of a defect correction apparatus 300 for a display device 2a according to the present embodiment will be described with reference to FIG. 4 to FIG. 7. FIG. 4 is a block diagram illustrating a configuration example of the manufacturing apparatus 100. FIG. 5 is a schematic diagram illustrating a configuration example of the defect correction apparatus 300. FIGS. 6A to 6D are diagrams for describing a defect correction method. FIG. 6A is a schematic diagram illustrating a state in which conductive foreign matter FB contaminates the red pixel Pr, FIG. 6B is a diagram illustrating an example of the determination of the position of a cutoff line CL (a cutoff position) being a laser light irradiation position, FIG. 6C is a diagram illustrating light-emitting states of the red pixel Pr, the green pixel Pg, and the blue pixel Pb, and FIG. 6D is a diagram illustrating the cathode electrode 25 after irradiation with laser light. FIG. 7 is a flowchart illustrating an example procedure (a defect correction method) at the defect correction apparatus 300.

Note that FIGS. 6B and 6C schematically illustrate the red pixel Pr, the green pixel Pg, and the blue pixel Pb that form one pixel. The size of each of the red pixel Pr, the green pixel Pg, and the blue pixel Pb corresponds to the size of each EL layer 24 when viewed from above the EL layer 24 (from the side where the sealing layer 6 and the like are formed). In addition, FIG. 6D illustrates a portion of the cathode electrode 25 including anode electrodes 22pr, 22pg, and 22pb (first electrodes) respectively forming the red pixel Pr, the green pixel Pg, and the blue pixel Pb illustrated in FIGS. 6B and 6C, when the display device 2a is viewed from above (in +Z-axis direction).

Hereinafter, a display device having a defect to be corrected in S4a illustrated in FIG. 1 (a display device after the light-emitting element layer 5 is formed and before the sealing layer 6 is formed) is referred to as “display device 2a”. A display device that is singulated and mounted with the electronic circuit board 60 is referred to as “display device 2” (see FIG. 2B) in the description. In addition, the target of defect detection at the defect correction apparatus 300 is each of the singulated display devices that have been cut along the cutting lines DL illustrated in FIG. 3. In FIG. 5, to simplify the illustration, a singulated display device before the sealing layer 6 is formed is illustrated as “display device 2a”.

### Manufacturing Apparatus

The manufacturing apparatus 100 that manufactures the display device 2 will be described with reference to FIG. 4. As illustrated in FIG. 4, the manufacturing apparatus 100 includes a film formation apparatus 200 forming each of the layers constituting the display device 2, the defect correction apparatus 300, which will be described later, a mounting apparatus 400 mounting the electronic circuit board 60 onto the terminal TM of the display device after the process in S12 illustrated in FIG. 1 is performed, and a controller 500 controlling these apparatuses.

### Defect Correction Apparatus

Next, the defect correction apparatus 300 will be described with reference to FIG. 5. As illustrated in FIG. 5, the defect correction apparatus 300 corrects a subpixel containing conductive foreign matter FB among a plurality of subpixels of the display device 2a so that the subpixel can display an image. In other words, the defect correction apparatus 300 corrects a subpixel (defective subpixel) containing conductive foreign matter FB so that a region other than a region containing the conductive foreign matter FB in the subpixel can emit light. The defect correction apparatus 300 includes a laser light source 301, a mirror 302, a scanner apparatus 303, an fθ lens 307, an image taking apparatus 308 (image taking unit), a control unit 309, and a mounting stand 310.

The laser light source 301 emits laser light. The peak wavelength of the laser light can be selected from a range from 200 nm to 1100 nm. A typical peak wavelength is, for example, 266 nm, 532 nm, or 1064 nm. The peak wavelength may be selected in accordance with the optical absorption property of the light-emitting element layer 5. In addition, the laser light emitted by the laser light source 301 has such intensity that at least the cathode electrode 25 can be cut when the display device 2a is irradiated with the laser light.

The mirror 302 is a member guiding the laser light emitted from the laser light source 301 to the scanner apparatus 303. In specific, the mirror 302 guides the laser light emitted from the laser light source 301 to an X-axis galvano mirror 304a.

Note that, in a case where the laser light source 301 and the scanner apparatus 303 are arranged so that the laser light from the laser light source 301 is directly incident on the scanner apparatus 303, the mirror 302 is not required. In addition, an optical system (such as a lens) adjusting the shape of the laser light may be disposed between the laser light source 301 and the mirror 302. In a case where the laser light from the laser light source 301 is guided directly to the scanner apparatus 303, this optical system is disposed between the laser light source 301 and the scanner apparatus 303.

The scanner apparatus 303 performs scanning with the laser light in the X-axis direction or the Y-axis direction on a front face of the mounting stand 310 (in an XY plane virtually determined on the front face). In specific, the scanner apparatus 303 guides the laser light emitted from the laser light source 301 to the display device 2a placed on the mounting stand 310, and changes the irradiation position of the laser light on the display device 2a (in specific, in the active region DA).

In the present embodiment, the scanner apparatus 303 includes the X-axis galvano mirror 304a, an X-axis drive unit 304b, a Y-axis galvano mirror 305a, a Y-axis drive unit 305b, and a drive apparatus 306. The X-axis galvano mirror 304a and the Y-axis galvano mirror 305a constitute a dual-axis galvano mirror.

The X-axis galvano mirror 304a enables scanning with the laser light in the X-axis direction on the front face of the mounting stand 310, and is disposed at an end portion of a shaft of the X-axis drive unit 304b. The X-axis drive unit 304b rotates the X-axis galvano mirror 304a in accordance with control at the drive apparatus 306. This enables scanning with the laser light in the X-axis direction on the front face of the display device 2a placed on the mounting stand 310.

The Y-axis galvano mirror 305a enables scanning with the laser light in the Y-axis direction on the front face of the mounting stand 310, and is disposed at an end portion of a shaft of the Y-axis drive unit 305b. The Y-axis drive unit 305b rotates the Y-axis galvano mirror 305a in accordance with control at the drive apparatus 306. This enables scanning with the laser light in the Y-axis direction on the front face of the display device 2a placed on the mounting stand 310.

The X-axis galvano mirror 304a and the Y-axis galvano mirror 305a are positioned precisely with respect to the mounting stand 310 so as to enable scanning with the laser light in the X-axis direction and the Y-axis direction on the front face of the mounting stand 310.

The drive apparatus 306 controls the amount of rotation of the shaft of each of the X-axis drive unit 304b and the Y-axis drive unit 305b separately on the basis of a control command from the control unit 309 (in specific, an image analysis unit 309a). In other words, the drive apparatus 306 drives the X-axis galvano mirror 304a and the Y-axis galvano mirror 305a separately.

Note that, in the present embodiment, the configuration using the X-axis galvano mirror 304a and the Y-axis galvano mirror 305a (dual-axis galvano mirror) is exemplified as the scanner apparatus 303. However, no such limitation is intended, and the scanner apparatus 303 may have any configuration enabling scanning with the laser light in the X-axis direction and the Y-axis direction on the front face of the mounting stand 310. For example, instead of the X-axis galvano mirror 304a and the Y-axis galvano mirror 305a, two polygon mirrors may be provided that enable scanning with the laser light in each of the X-axis direction and the Y-axis direction on the front face.

The fθ lens 307 allows the laser light reflected off the Y-axis galvano mirror 305a to concentrate on the front face of the display device 2a placed on the mounting stand 310. With the fθ lens 307, the size of the laser light on the front face can be controlled in a detailed manner. The major axis of the irradiation region formed by the laser light on the front face has a length of, for example, approximately 2 μm (in a case of a substantially circular shape, the diameter is approximately 2 μm). In other words, the laser light emitted from the scanner apparatus 303 is controlled so as to have the size of the above-described irradiation region.

The image taking apparatus 308 takes an image of the front face of the display device 2a (in specific, the active region DA) placed on the mounting stand 310 in accordance with control at the control unit 309. The image taking apparatus 308 outputs the image acquired by the image taking and including the active region DA, to the image analysis unit 309a of the control unit 309.

The control unit 309 controls each member of the defect correction apparatus 300 in a centralized manner. In specific, the control unit 309 controls the emission of the laser light from the laser light source 301, the rotation of the X-axis galvano mirror 304a and the Y-axis galvano mirror 305a driven by the drive apparatus 306, and the image taking of the display device 2a at the image taking apparatus 308.

The control unit 309 includes the image analysis unit 309a. The image analysis unit 309a analyzes the image of the display device 2a taken by the image taking apparatus 308 to determine whether conductive foreign matter FB contaminates a subpixel included in the display device 2a and, in a case where such contamination is occurring, identifies the position and shape of the conductive foreign matter FB. This shape indicates a planar shape of the conductive foreign matter FB when the display device 2a is viewed from above. The image analysis unit 309a then determines the laser light irradiation position with respect to the display device 2a on the basis of the result of the identification.

For example, the image analysis unit 309a identifies, in the acquired image, a region having a predetermined gray scale value, for example, as a region containing conductive foreign matter FB, thereby identifying the position and shape. Alternatively, the image analysis unit 309a may specify a plurality of subpixels included in the display device 2a in the acquired image, and may identify a region differing in brightness by a predetermined value or greater from a peripheral region in each of the specified subpixels, as a region containing conductive foreign matter FB.

Alternatively, the image analysis unit 309a may use the acquired image to generate a difference image indicating a difference in brightness between a defective subpixel and a normal subpixel (a subpixel brought into a light-emitting state when the light-emitting element layer 5 starts light emission) having the same color as and adjacent to the defective subpixel, for example, and may analyze the difference image to identify the position and shape. By using the difference image, the contrast of the conductive foreign matter FB to its periphery can be enhanced, and the position of the conductive foreign matter FB can be detected in a detailed manner (e.g., in the order of 100 nm).

Here, in a case where conductive foreign matter FB is caught in the light-emitting element layer 5 (between the anode electrode 22 and the cathode electrode 25) in the display device 2a including the light-emitting element layer 5, an attempt at light emission from the defective subpixel fails. In specific, as illustrated in FIG. 6A, in a case where conductive foreign matter FB contaminates a subpixel (the red pixel Pr in the example illustrated in FIGS. 6A, 6B, 6C, and 6D) so that the anode electrode 22 and the cathode electrode 25 are electrically connected with each other, the light emission of the light-emitting element layer 5 causes a short circuit between the anode electrode 22 and the cathode electrode 25, bringing the defective subpixel into a non light-emitting state. In addition, the pixel including the defective subpixel becomes a pixel having a defect (defective pixel).

As illustrated in FIG. 6B, the image analysis unit 309a identifies the region containing the conductive foreign matter FB in the acquired image and then determines the irradiation position (the position of the cutoff line CL) on the display device 2a, so that scanning with the laser light can be performed along the outer periphery of a corresponding region (a region where the conductive foreign matter FB actually exits; the shaded region in the same drawing) in the display device 2a. By determining the irradiation position in this way, the laser light can be radiated along the shape of the conductive foreign matter FB.

In addition, the image analysis unit 309a identifies a region slightly larger than the size of the conductive foreign matter FB when the display device 2a is viewed from above, as the region containing the conductive foreign matter FB. In other words, the image analysis unit 309a determines such an irradiation position that the laser light is radiated toward a position remote from the outer periphery of the conductive foreign matter FB by a predetermined distance (e.g., approximately several nm). By providing a margin in this way, even in a case where the actual laser light irradiation position is misaligned from the irradiation position determined by the image analysis unit 309a, the periphery of the conductive foreign matter FB can be cut.

In the present embodiment, as illustrated in FIGS. 6A and 6B, the conductive foreign matter FB does not extend over adjacent subpixels but exists in one subpixel. Thus, as illustrated in FIG. 6B, the image analysis unit 309a determines such an irradiation position as to extend along the outer periphery of the region containing the conductive foreign matter FB and to surround (enclose) the region, in the defective subpixel. The image analysis unit 309a then determines the time-varying amount of the rotation of the shafts of the X-axis drive unit 304b and the Y-axis drive unit 305b so that scanning with the laser light emitted from the laser light source 301 is performed on the determined irradiation position, and outputs the result of the determination to the drive apparatus 306.

The scanner apparatus 303 radiates the laser light toward the outer periphery (the cutoff line CL illustrated in FIG. 6B) of the region containing the conductive foreign matter FB in such a manner that the conductive foreign matter FB is surrounded, in accordance with control at the image analysis unit 309a. This cuts the cathode electrode 25 along the irradiation position and electrically divides the region containing the conductive foreign matter FB from the other region in the defective subpixel. In other words, the scanner apparatus 303 radiates the laser light toward the defective subpixel to enable such division.

As a result, the region containing the conductive foreign matter FB can be insulated from the other region (the region containing the conductive foreign matter FB can be made into an island) in the defective subpixel. Thus, as illustrated in FIG. 6C, while only the region containing the conductive foreign matter FB is made into a non light-emitting region An, the other region (light-emitting region Ai) can emit light in the defective subpixel. That is, when light is emitted from even the defective subpixel, the region other than the region containing the conductive foreign matter FB in the defective subpixel can be brought into a light-emitting state. That is, as illustrated in FIG. 6D, the scanner apparatus 303 electrically divides the cathode electrode 25 into a light emission corresponding portion Ai1 corresponding to the light-emitting region Ai and a non light emission corresponding portion An1 corresponding to the non light-emitting region An, in the defective subpixel.

Note that the intensity of the laser light emitted by the laser light source 301 may be controlled so that the region containing the conductive foreign matter FB is electrically divided from the other region. For example, the laser light may have such intensity that the EL layer 24 and/or the anode electrode 22 in addition to the cathode electrode 25 can be cut.

FIGS. 6A, 6B, 6C, and 6D exemplify a case in which conductive foreign matter FB is contained only in one red pixel Pr; however, no such limitation is intended. Even in a case where conductive foreign matter FB contaminates one green pixel Pg or one blue pixel Pb, the irradiation position is determined as described above. Even in a case where a plurality of such defective subpixels exist, or even in a case where a plurality of pieces of conductive foreign matter FB exist in one subpixel, the irradiation position is determined similarly.

The mounting stand 310 is for placing thereon the display device 2a being a target of image taking at the image taking apparatus 308 and being a target of the determination of whether a defective subpixel exists (in a case where a defective subpixel exists, being a target of the correction of the defective subpixel). In specific, the display device 2a before the formation of the sealing layer 6 and singulation is placed on the mounting stand 310. Note that the present embodiment has such a configuration that the scanner apparatus 303 performs scanning with the laser light emitted from the laser light source 301 on the front face of the display device 2a; however, the mounting stand 310 may be moved in the X-axis direction or the Y-axis direction to perform scanning with the laser light on the front face.

### Display Device After Defect Correction

As described above, the display device 2a having at least one defective subpixel among a plurality of subpixels is subjected to correction by irradiation with the laser light. As a result, as illustrated in FIG. 6C, the display device 2a (display device 2) has one region of the defective subpixel being the non light-emitting region An conforming to the planar shape of the conductive foreign matter FB and the other region being the light-emitting region Ai. As illustrated in FIG. 6D, this display device 2a includes the light emission corresponding portion Ai1 and the non light emission corresponding portion An1 that are not electrically connected with each other. In the present embodiment, the non light emission corresponding portion An1 is surrounded by the light emission corresponding portion Ai1 in the defective subpixel.

### Defect Correction Method

Next, an example procedure at the defect correction apparatus 300 will be described with reference to FIG. 7. In other words, a specific example of the process in step S4a illustrated in FIG. 1 will be described.

As illustrated in FIG. 7, when a display device 2a is placed on the mounting stand 310, the image taking apparatus 308 takes an image of the active region DA corresponding to one singulated display device 2 (step S21). The image analysis unit 309a analyzes the image acquired by the image taking apparatus 308 to determine whether conductive foreign matter FB exists in each of a plurality of subpixels included in the active region DA (step S22).

When determining that conductive foreign matter FB exists in at least one of the subpixels in the active region DA as a result of the analysis (YES in step S22), the image analysis unit 309a identifies a region containing the conductive foreign matter FB in the subpixel (defective subpixel) (in other words, the position and shape of the conductive foreign matter FB) and determines a laser light irradiation position in the defective subpixel (step S23).

On the basis of the result of the determination of the irradiation position at the image analysis unit 309a, the scanner apparatus 303 radiates laser light emitted from the laser light source 301 along the outer periphery of the region containing the conductive foreign matter FB in the defective subpixel (step S24: laser light radiation step). In specific, the drive apparatus 306 controls orientations of the X-axis galvano mirror 304a and the Y-axis galvano mirror 305a to enable scanning with the laser light along the irradiation position determined by the image analysis unit 309a. This electrically divides the region containing the conductive foreign matter FB from the other region.

In a case where a plurality of regions containing conductive foreign matter FB are identified in the active region DA, the scanner apparatus 303 radiates the laser light along the outer periphery of each of the regions to sequentially make each region into an island. In other words, the scanner apparatus 303 radiates the laser light toward all the identified irradiation positions to make all the identified regions into islands.

After the scanner apparatus 303 completes the radiation of the laser light toward all the identified irradiation positions, the control unit 309 controls a transport apparatus (not illustrated) transporting the display device 2a to move a subsequent active region DA being a target of the determination of whether a defective subpixel exists to a position opposing to the scanner apparatus 303 and the image taking apparatus 308. When the image analysis unit 309a determines that no conductive foreign matter FB contaminates any subpixel constituting the active region DA in step S22 described above (NO in step S22), the control unit 309 also moves a subsequent active region DA to the above-described position.

After the determination of whether a defective subpixel exists is complete for all the active regions DA of the display device 2a, the control unit 309 controls the transport apparatus to place another display device 2a before singulation on the mounting stand 310. Note that the display device 2a after the completion of the determination of whether a defective subpixel exists in all the active regions DA is subjected to a process in a subsequent step (step S5 illustrated in FIG. 1).

### Effects of Present Embodiment

Here, it is also conceivable that a defective subpixel may be corrected using a pattern that transmits laser light as in the technique of PTL 1. In this case, the pattern is prepared and has a fixed shape (e.g., a circle or a quadrilateral). Unfortunately, even in a case where a plurality of patterns having predetermined shapes or sizes are prepared, there are limitations on the shape, size, and number. Thus, in a case where no pattern conforms to the shape or size of conductive foreign matter FB, laser light may not be radiated precisely in conformance to the shape or size of the conductive foreign matter FB. In this case, laser light may be radiated toward a region unnecessarily greater than the size of the conductive foreign matter FB, so that the great region is unnecessarily made into a non light-emitting region in the defective subpixel, causing a light-emitting region to decrease needlessly. In a case that conductive foreign matter FB contaminates an end region of a pixel, even a portion of an adjacent subpixel having no contamination by any conductive foreign matter FB may be made into a non light-emitting region. In addition, a greater non light-emitting region of the display device used especially as a high-resolution panel may be recognized as a black region (black spot) with a higher probability.

Furthermore, in a case where laser light is radiated toward the outer periphery of a region containing conductive foreign matter FB without using the pattern, it is conceivable that a plurality of patterns for prescribing the sizes of the irradiation range (e.g., a rectangle) of the laser light are prepared. In this case, a pattern is selected in conformance to the size of the conductive foreign matter FB, and laser light is radiated. Unfortunately, similar to the above case, there is a limitation on the prepared pattern. Thus, in a case that no pattern conforms to the size of the conductive foreign matter FB, the light-emitting region may decrease more than necessary.

In this way, in a case where laser light is radiated using a prescribed pattern determined preliminarily, the light-emitting region may decrease more than necessary.

On the other hand, in the defect correction apparatus 300, the scanner apparatus 303 functions as a laser light radiation unit that radiates the laser light emitted from the laser light source 301 along the outer periphery of a region containing conductive foreign matter FB in a defective subpixel in conformance to the shape of the conductive foreign matter FB, without using the above-described prescribed pattern.

In specific, the scanner apparatus 303 performs scanning with the laser light along the outer periphery in the defective subpixel and electrically divides the region containing the conductive foreign matter FB from the other region. In the present embodiment, the cathode electrode 25 is electrically divided into the light emission corresponding portion Ai1 and the non light emission corresponding portion An1 in the defective subpixel. In addition, to achieve the radiation of the laser light, the image analysis unit 309a analyzes an image of the display device 2a acquired by the image taking apparatus 308 to identify the position and shape of the conductive foreign matter FB in the defective subpixel, thereby determining the laser light irradiation position in the defective subpixel.

This enables the defect correction apparatus 300 to correct the defective subpixel in accordance with the shape of the conductive foreign matter FB. In specific, the defect correction apparatus 300 can precisely extract the shape of the conductive foreign matter FB through the above-described image analysis and can thus correct the defective subpixel precisely in accordance with the shape of the conductive foreign matter FB.

Accordingly, the defect correction apparatus 300 enables the defective subpixel to emit light (to be normalized) without decreasing the light-emitting region in the defective subpixel more than necessary. In other words, the light-emitting region Ai can be secured to maximum in the defective subpixel. In addition, the non light-emitting region An does not increase needlessly, so that the possibility of recognition as a black region can be reduced.

Furthermore, after the defect correction apparatus 300 corrects a defect in the display device 2a having a defective subpixel, one region of the defective subpixel is made into a non light-emitting region An conforming to the planar shape of the conductive foreign matter FB, and the other region is made into a light-emitting region Ai. Thus, the display device 2a having the non light-emitting region An conforming to the planar shape of the conductive foreign matter FB can be provided. That is, the display device 2a (and furthermore the display device 2) in which the defect in the subpixel is precisely corrected can be provided. Moreover, in the above-described display device 2a, the light emission corresponding portion Ai1 and the non light emission corresponding portion An1 are not electrically connected with each other in the defective subpixel. Thus, the display device 2a having the light-emitting region Ai and the non light-emitting region An described above can be achieved.

In a case where laser light is radiated through a pattern that transmits the laser light as in the technique of PTL 1, it is conceivable that the radiation is performed toward the irradiation position in a fixed manner (with one shot) instead of scanning with the laser light. Laser light generally has an intensity distribution (e.g., Gaussian distribution) in a plane orthogonal to the traveling direction of the laser light. In a case where scanning with laser light is not performed, this intensity distribution may not allow proper cutting (especially in the cathode electrode 25 having a thin film thickness). On the other hand, in the defect correction apparatus 300, the scanner apparatus 303 performs scanning with the laser light (in specific, scanning with the laser light formed into a detailed shape by the fθ lens 307), thereby cutting off the periphery of the region containing the conductive foreign matter FB. Thus, while the intensity distribution of the laser light is less prone to affect the operation, at least the cathode electrode 25 can be cut. In other words, at least the cathode electrode 25 can be cut properly.

Note that the above-described laser light radiation unit has a basic configuration composed of the scanner apparatus 303. However, no such limitation is intended, and the laser light radiation unit may include the laser light source 301 emitting laser light used for scanning. In addition, the laser light radiation unit may include the fθ lens 307 forming the shape of the laser light in detail.

The scanner apparatus 303 radiates the laser light along the outer periphery of the region containing the conductive foreign matter FB. In other words, the scanner apparatus 303 is not required to radiate the laser light toward the entire face of the region but radiates the laser light only toward the edge portion of the region. This is because the light-emitting element layer 5 of the display device 2a to be inspected by the defect correction apparatus 300 is achieved by any of an organic light emitting diode, an inorganic light emitting diode, and a quantum dot light emitting diode as described above. On the other hand, in a case of a display device using liquid crystal, laser light needs to be radiated toward the entire face of the region to make the region into a non light-emitting region. Thus, with the display device 2a being an inspection target, the scanner apparatus 303 can shorten the time of the correction processing of a defective subpixel in comparison with the case of a display device using liquid crystal. The shortening of the processing time results in the reduction of power consumption in emitting the laser light.

However, in a case of focusing only on the formation of a non light-emitting region An in a defective subpixel without considering the above-described point, the scanner apparatus 303 may radiate the laser light toward the entire face of the region including the outer periphery of the region, for example.

### Second Embodiment

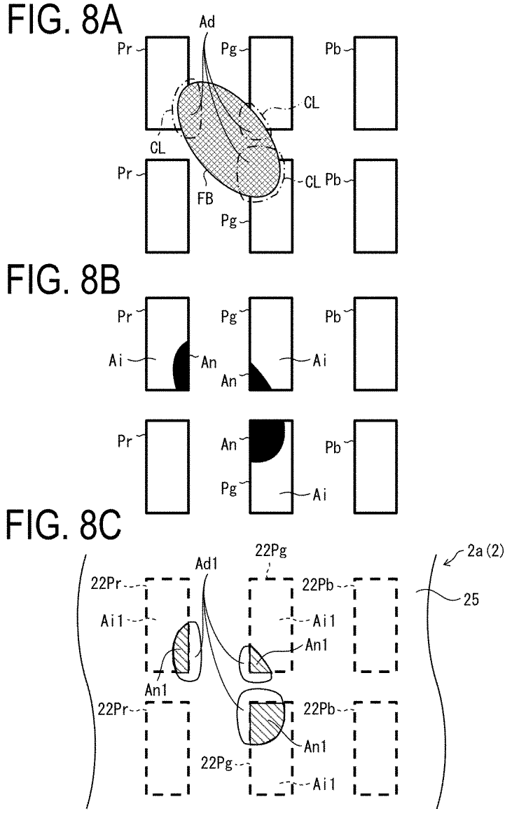

Another embodiment of the disclosure will be described below with reference to FIGS. 8A, 8B, and 8C. Note that members having the same function as the members stated in the embodiment above are appended with the same reference signs for the sake of description, and the description thereof is omitted. FIGS. 8A to 8C are diagrams for describing a defect correction method. FIG. 8A is a diagram schematically illustrating a state in which conductive foreign matter FB contaminates a plurality of subpixels and illustrating an example of the determination of the position of a cutoff line CL being a laser light irradiation position, FIG. 8B is a diagram illustrating light-emitting states of the red pixel Pr, the green pixel Pg, and the blue pixel Pb, and FIG. 8C is a diagram illustrating the cathode electrode 25 after irradiation with laser light.

As illustrated in FIG. 8A, the present embodiment differs from the first embodiment in that conductive foreign matter FB extends over (lies across) a plurality of adjacent subpixels. In the example illustrated in FIG. 8A, one piece of conductive foreign matter FB extends over one red pixel Pr and two green pixels Pg. In this case, similar to the first embodiment, the subpixels contaminated by the conductive foreign matter FB are defective subpixels. In the example illustrated in FIG. 8A, all the three subpixels consisting of the red pixel Pr and the green pixels Pg are defective subpixels (the two pixels including these subpixels are defective pixels).

Note that, in a case where the conductive foreign matter FB exists such that adjacent anode electrodes 22 are electrically connected with each other, the laser light emitted by the laser light source 301 has such intensity as to cut the EL layer 24 and the anode electrode 22 in addition to the cathode electrode 25. However, in a portion where the conductive foreign matter FB contaminates the subpixels such that the anode electrode 22 and the cathode electrode 25 are electrically connected with each other (in such a case), similar to the first embodiment, at least the anode electrode 22 may be cut.

In the present embodiment, similar to the first embodiment, the image analysis unit 309a determines whether conductive foreign matter FB exits in each of the subpixels in the active region DA and, in a case where conductive foreign matter FB exists in subpixels, identifies the position and shape of the conductive foreign matter FB. The scanner apparatus 303 radiates the laser light along the outer periphery of a region containing the conductive foreign matter FB in the defective subpixels on the basis of the result of analysis at the image analysis unit 309a.

In other words, in the present embodiment, the scanner apparatus 303 radiates the laser light along the outer periphery of a portion, contained in each of a plurality of adjacent defective subpixels, of the conductive foreign matter FB extending over the defective subpixels. In specific, the scanner apparatus 303 radiates the laser light so as to electrically divide the region containing the conductive foreign matter FB from the other region in each of the defective subpixels. To achieve the radiation, the image analysis unit 309a determines the laser light irradiation position (the position of the cutoff line CL) so as to electrically divide the region containing the conductive foreign matter FB from the other region in each of the defective subpixels.

In the example illustrated in FIG. 8A, the conductive foreign matter FB exists in end regions of the red pixel Pr and the two green pixels Pg containing the conductive foreign matter FB. The image analysis unit 309a determines such an irradiation position that the end region, including the region containing the conductive foreign matter FB, of each of the defective subpixels is cut off from the defective subpixel.

In specific, as illustrated in FIG. 8A, the image analysis unit 309a identifies defective regions Ad containing the conductive foreign matter FB in the display device 2a. The defective region Ad is a region including (1) a region containing the conductive foreign matter FB in each of the red pixel Pr and the two green pixels Pg and (2) a region adjacent to the aforementioned region and containing a portion of the conductive foreign matter FB in a portion other than these subpixels (e.g., a portion of the bank 23 illustrated in FIG. 2A). That is, the defective region Ad is a region including each of the above-described end regions and a peripheral region thereof that each constitutes a portion of the conductive foreign matter FB (a portion of the planar shape of the conductive foreign matter FB) when the display device 2a is viewed from above. The image analysis unit 309a determines the outer periphery, surrounding the identified defective region Ad, of the defective region Ad as a laser light irradiation position.

The scanner apparatus 303 then radiates the laser light along the determined irradiation position. In specific, the scanner apparatus 303 radiates the laser light along the outer periphery of the defective region Ad (cutoff line CL). As illustrated in FIG. 8B, this enables only the region containing the conductive foreign matter FB to be made into a non light-emitting region An and enables a light-emitting region Ai other than the aforementioned region to emit light, in each of the subpixels when the light-emitting element layer 5 emits light.

That is, as illustrated in FIG. 8C, the display device 2a (display device 2) after irradiation with the laser light includes the light emission corresponding portion Ai1 and the non light emission corresponding portion An1 that are not electrically connected with each other, in each of the red pixel Pr and the two green pixels Pg.

As illustrated in FIG. 8C, in at least the cathode electrode 25 of the display device 2a, a defect corresponding portion Ad1 corresponding to the defective region Ad cut off along the cutoff line CL is not electrically connected with the other portion. Thus, the defect corresponding portion Ad1 is a portion corresponding to a region including a portion of the planar shape of the conductive foreign matter FB. In specific, the defect corresponding portion Ad1 is a portion including (1) the non light-emitting region An of each of the red pixel Pr and the two green pixels Pg (the non light emission corresponding portion An1 corresponding to each of the non light-emitting regions An) and (2) a partial region adjacent to each of the non light-emitting regions An (non light emission corresponding portions An1) and other than the red pixel Pr and the two green pixels Pg.

### Effects of Present Embodiment

In this way, in the present embodiment, even in a case where conductive foreign matter FB extends over a plurality of adjacent subpixels, the scanner apparatus 303 radiates the laser light so as to electrically divide the region containing the conductive foreign matter FB from the other region in each of the subpixels. Thus, even in this case, similar to the first embodiment, the defective subpixels can be corrected precisely.

Furthermore, unlike the first embodiment, the present embodiment cuts the entire outer periphery of each of the defective regions Ad instead of cutting the entire outer periphery of the conductive foreign matter FB. This is because it is only required to electrically divide the region containing the conductive foreign matter FB from the other region in each of the defective subpixels.

Moreover, even in a case where conductive foreign matter FB extends over a plurality of adjacent subpixels, similar to the first embodiment, the present embodiment can provide a display device 2a (and furthermore display device 2) having the non light-emitting regions An conforming to the planar shape of the conductive foreign matter FB.

### Third Embodiment

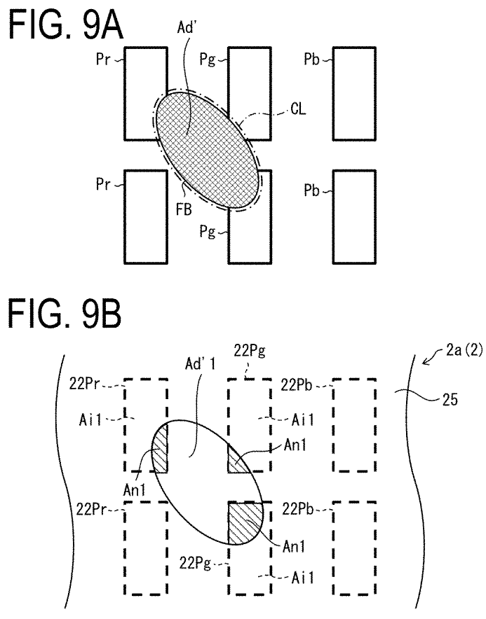

Yet another embodiment of the disclosure will be described with reference to FIGS. 9A and 9B. Note that members having the same function as the members stated in the embodiment above are appended with the same reference signs for the sake of description, and the description thereof is omitted. FIGS. 9A and 9B are diagrams for describing a defect correction method. FIG. 9A is a diagram schematically illustrating a state in which conductive foreign matter contaminates a plurality of subpixels and illustrating an example of the determination of the position of a cutoff line CL being a laser light irradiation position, and FIG. 9B is a diagram illustrating the cathode electrode 25 after irradiation with laser light.

As illustrated in FIG. 9A, in the present embodiment, similar to the second embodiment, conductive foreign matter FB extends over a plurality of adjacent subpixels. However, the present embodiment differs from the second embodiment in the method of determining a laser light irradiation position (the position of the cutoff line CL).

In the present embodiment, similar to the second embodiment, in a case where the conductive foreign matter FB exists in subpixels, the image analysis unit 309a identifies the position and shape of the conductive foreign matter FB. However, in the present embodiment, the image analysis unit 309a determines whether the conductive foreign matter FB exists in the entire active region DA instead of in each of the subpixels. The image analysis unit 309a then determines the laser light irradiation position so as to electrically divide the region containing the conductive foreign matter FB from the other region in each of the defective subpixels. The scanner apparatus 303 radiates the laser light along the outer periphery of a portion, contained in each of the adjacent defective subpixels, of the conductive foreign matter FB extending over the defective subpixels, on the basis of the determined laser light irradiation position.

In the example illustrated in FIG. 9A, the image analysis unit 309a identifies a defective region Ad′ containing the conductive foreign matter FB in the display device 2a. In the present embodiment, the image analysis unit 309a determines a region containing the entire conductive foreign matter FB (the entire planar shape of the conductive foreign matter FB) that extends over a red pixel Pr and two green pixels Pg being defective subpixels and a portion other than these defective subpixels (e.g., a portion of the bank 23 illustrated in FIG. 2A), as the defective region Ad′. The image analysis unit 309a determines the outer periphery, surrounding the identified defective region Ad′, of the defective region Ad′ as a laser light irradiation position.

The scanner apparatus 303 then radiates the laser light along the determined irradiation position. In specific, the scanner apparatus 303 radiates the laser light along the outer periphery of the defective region Ad′ (cutoff line CL). That is, in the present embodiment, the entire outer periphery of the region containing the conductive foreign matter FB is cut. Similar to the second embodiment, this also enables only the region containing the conductive foreign matter FB to be made into a non light-emitting region An and enables a light-emitting region Ai other than the aforementioned region to emit light, in each of the defective subpixels when the light-emitting element layer 5 emits light (see FIG. 8B).

That is, similar to the second embodiment, as illustrated in FIG. 9B, the display device 2a (display device 2) after irradiation with the laser light includes the light emission corresponding portion Ai1 and the non light emission corresponding portion An1 that are not electrically connected with each other, in each of the red pixel Pr and the two green pixels Pg.

As illustrated in FIG. 9B, in at least the cathode electrode 25 of the display device 2a, a defect corresponding portion Ad′1 corresponding to the defective region Ad′ cut off along the cutoff line CL is not electrically connected with the other portion. Thus, the defect corresponding portion Ad′1 is a portion corresponding to a region including the entire planar shape of the conductive foreign matter FB, which differs from the defect corresponding portion Ad1 of the second embodiment. In other words, the defect corresponding portion Ad′1 includes not only a partial region adjacent to each of the non light emission corresponding portions An1 and other than the red pixel Pr and the two green pixels Pg (the adjacent defective subpixels) but also a region that is not adjacent to the non light emission corresponding portions An1. That is, in the present embodiment, in at least the cathode electrode 25, the non light emission corresponding portions An1 of the red pixel Pr and the two green pixels Pg are electrically connected with each other but are not electrically connected with the other portion.

### Effects of Present Embodiment

In this way, similar to the second embodiment, even in a case where conductive foreign matter FB extends over a plurality of adjacent subpixels, the scanner apparatus 303 can precisely correct the defective subpixels.

Furthermore, in the present embodiment, in the above-described case, the laser light irradiation position is determined so that the entire outer periphery of the planar shape of the conductive foreign matter FB can be cut off. Thus, in this case, the image analysis unit 309a can set the irradiation position more readily than the case of the second embodiment.

Moreover, similar to the second embodiment, the present embodiment can provide a display device 2a (and furthermore display device 2) having the non light-emitting region An conforming to the planar shape of the conductive foreign matter FB extending over the adjacent subpixels.

### Fourth Embodiment

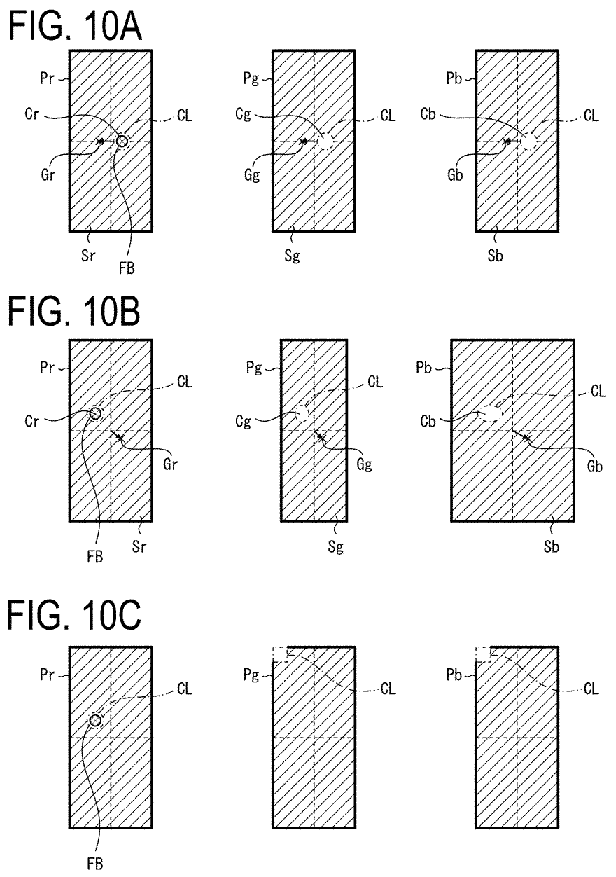

Yet another embodiment of the disclosure will be described below with reference to FIGS. 10A, 10B, and 10C. Note that members having the same function as the members stated in the embodiment above are appended with the same reference signs for the sake of description, and the description thereof is omitted. FIGS. 10A to 10C are diagrams for describing defect correction methods. FIG. 10A is a diagram illustrating a defect correction method for subpixels having the same size (area) when the display device 2a is viewed from above, FIG. 10B is a diagram illustrating a defect correction method for subpixels having different sizes, and FIG. 10C is a diagram for describing a defect correction method, differing from that in FIG. 10A, for subpixels having the same size.

As illustrated in FIGS. 10A, 10B, and 10C, in the present embodiment, the scanner apparatus 303 radiates the laser light toward partial regions of normal subpixels, the normal subpixels being subpixels containing no conductive foreign matter FB, of a pixel (defective pixel) including a defective subpixel. In specific, the scanner apparatus 303 radiates the laser light toward the defective subpixel and the normal subpixels to form a non light-emitting region and a light-emitting region in each of the defective subpixel and the normal subpixels. In this way, the present embodiment differs from the above-described embodiments in that, in the defective pixel, the laser light is also radiated toward the normal subpixels to form non light-emitting regions and light-emitting regions in the normal subpixels.

FIGS. 10A, 10B, and 10C each illustrate a case in which conductive foreign matter FB contaminates a red pixel Pr. That is, the red pixel Pr is a defective subpixel, and the green pixel Pg and the blue pixel Pb are normal subpixels included in the defective pixel. The following describes a case in which the defective subpixel is a red pixel Pr, and the normal subpixels are a green pixel Pg and a blue pixel Pb. In FIGS. 10A and 10C, the red pixel Pr, the green pixel Pg, and the blue pixel Pb have the same size; however, in FIG. 10B, the subpixels have different sizes. In the example illustrated in FIG. 10B, the green pixel Pg is smallest among the subpixels, and the blue pixel Pb is largest among the subpixels.

In FIGS. 10A and 10B, similar to the above-described embodiments, the laser light is radiated along the outer periphery of the region containing the conductive foreign matter FB (cutoff line CL). This electrically divides at least the cathode electrode 25, and thus, in the red pixel Pr, the inside of the cutoff line CL is made into a non light-emitting region, and the outside is made into a light-emitting region (diagonally shaded portion).

In addition, the scanner apparatus 303 radiate the laser light toward the green pixel Pg and the blue pixel Pb with the ratio of the light-emitting regions of the red pixel Pr, the green pixel Pg, and the blue pixel Pb coinciding with the ratio of the sizes of the subpixels.

In other words, the scanner apparatus 303 radiates the laser light toward the red pixel Pr, the green pixel Pg, and the blue pixel Pb so that the relationship Sr:Sg:Sb=(Sr−Cr):(Sg−Cg):(Sb−Cb) is satisfied. In this relationship, Sr is a size (area) of the entire red pixel Pr, Sg is a size of the entire green pixel Pg, Sb is a size of the entire blue pixel Pb, Cr is a size of the non light-emitting region of the red pixel Pr, Cg is a size of the non light-emitting region of the green pixel Pg, and Cb is a size of the non light-emitting region of the blue pixel Pb. At this time, the size of the light-emitting region of the red pixel Pr is represented as Sr−Cr, the size of the light-emitting region of the green pixel Pg is represented as Sg−Cg, and the size of the light-emitting region of the blue pixel Pb is represented as Sb−Cb.

That is, the scanner apparatus 303 forms light-emitting regions in accordance with the sizes of the red pixel Pr, the green pixel Pg, and the blue pixel Pb, in the red pixel Pr, the green pixel Pg, and the blue pixel Pb. In specific, the scanner apparatus 303 forms such light-emitting regions (non light-emitting regions) in the green pixel Pg and the blue pixel Pb that the ratio of the size of the light-emitting region (non light-emitting region) formed in the red pixel Pr to the size of the red pixel Pr is maintained even in the green pixel Pg and the blue pixel Pb being normal subpixels. The image analysis unit 309a identifies the size of each of the subpixels and the size of the light-emitting region (non light-emitting region) formed in the red pixel Pr to determine the size of the light-emitting regions (non light-emitting regions) to be formed in the green pixel Pg and the blue pixel Pb.

In the example illustrated in FIG. 10A, the subpixels have the same size, so that the light-emitting regions of the subpixels all have the same size. On the other hand, in FIG. 10B, the subpixels have different sizes. Thus, the light-emitting regions of the subpixels have different sizes in accordance with the ratio of the sizes of the subpixels. In FIG. 10B, in a case of Sr:Sg:Sb=2:1:3, for example, the sizes of the light-emitting regions of the subpixels (in specific, the sizes of the light-emitting regions of the green pixel Pg and the blue pixel Pb) are determined so that the relationship (Sr−Cr):(Sg−Cg):(Sb−Cb)=2:1:3 is satisfied.

In addition, the scanner apparatus 303 radiates the laser light toward the green pixel Pg and the blue pixel Pb so that the non light-emitting regions of the green pixel Pg and the blue pixel Pb are formed in positions, corresponding to the position of the non light-emitting region in the red pixel Pr, in the green pixel Pg and the blue pixel Pb.

In this case, for example, the image analysis unit 309a identifies the position of the barycenter (the center of luminance) Gr of the light-emitting region after the non light-emitting region is formed, in the red pixel Pr. Then, the image analysis unit 309a identifies the positions of the barycenters Gg and Gb, corresponding to the position of the barycenter Gr in the red pixel Pr, in the green pixel Pg and the blue pixel Pb on the basis of the size (shape) of the red pixel Pr and the relationship of size with the green pixel Pg and the blue pixel Pb. The image analysis unit 309a applies, for example, a vector to the green pixel Pg to determine the position of the barycenter Gg. The vector is from the center of the red pixel Pr toward the barycenter Gr, and in the vector, the rate of the size (for example, width) of the green pixel Pg in a predetermined direction to the size of the red pixel Pr in the predetermined direction is reflected. The same applies to the barycenter Gb. The image analysis unit 309a then identifies the position of the non light-emitting region (the position of the cutoff line CL) in each of the green pixel Pg and the blue pixel Pb so that the light-emitting regions of the green pixel Pg and the blue pixel Pb have the barycenters Gg and Gb. This enables the light-emitting regions of the subpixels to have the barycenters Gr, Gg, and Gb aligned in position with each other.

In FIG. 10A, the red pixel Pr, the green pixel Pg, and the blue pixel Pb have the same size (shape). Thus, the light-emitting regions (non light-emitting regions) are formed in the green pixel Pg and the blue pixel Pb so as to have the barycenters Gg and Gb defined in positions corresponding to the position of the barycenter Gr in the red pixel Pr. On the other hand, in FIG. 10B, the red pixel Pr, the green pixel Pg, and the blue pixel Pb have different widths. Thus, the barycenter Gg or Gb is defined in a position in which the rate of the width of the green pixel Pg or the blue pixel Pb to the width of the red pixel Pr is reflected, and the light-emitting regions (non light-emitting regions) are formed in the green pixel Pg and the blue pixel Pb so as to have the defined barycenters Gg and Gb.

In other words, the scanner apparatus 303 forms the light-emitting regions of the green pixel Pg and the blue pixel P so that the light-emitting regions of the green pixel Pg and the blue pixel P have barycenters in positions, corresponding to the barycenter position of the light-emitting region in the red pixel Pr, in the green pixel Pg and the blue pixel P. The scanner apparatus 303 radiates the laser light so as to form the light-emitting regions in the green pixel Pg and the blue pixel Pb in this way.

Note that the non light-emitting regions formed in the green pixel Pg and the blue pixel Pb may not correspond to the position in which the non light-emitting region is formed in the red pixel Pr as illustrated in FIGS. 10A and 10B. For example, as illustrated in FIG. 10C, the scanner apparatus 303 may radiate the laser light toward the green pixel Pg and the blue pixel Pb so that the non light-emitting regions of the green pixel Pg and the blue pixel Pb are formed in end regions, corresponding to an end region closer to the position of the non light-emitting region in the red pixel Pr, in the green pixel Pg and the blue pixel Pb. In this case, the image analysis unit 309a determines the end regions where the non light-emitting regions are formed in the green pixel Pg and the blue pixel Pb so that the positions of the barycenters Gg and Gb in the green pixel Pg and the blue pixel Pb do not significantly differ from the position of the barycenter Gr in the red pixel Pr.

Note that, in a case where one pixel has two defective subpixels, the position of the cutoff line CL (the position of the light-emitting region) in the normal subpixel may be determined in accordance with either of the defective subpixels.

### Display Device After Defect Correction

As described above, as a result of the irradiation with the laser light, the display device 2a (display device 2) of the present embodiment includes a normal subpixel having one region being a non light-emitting region and the other region being a light-emitting region, in the defective pixel. That is, in this display device 2a, at least the cathode electrode 25 in the normal subpixel includes a light emission corresponding portion corresponding to the light-emitting region and a non light emission corresponding portion corresponding to the non light-emitting region, the portions being electrically divided.

Furthermore, in the display device 2a, the ratio of the sizes of the light-emitting regions of the subpixels substantially coincides with the ratio of the sizes of the subpixel. In addition, as illustrated in FIGS. 10A and 10B, the non light-emitting region of the normal subpixel may be formed in a position, corresponding to the position of the non light-emitting region in the defective subpixel, in the normal subpixel. In other words, the light-emitting region may be provided in the normal subpixel so as to have a barycenter in a position, corresponding to the barycenter position of the light-emitting region in the defective subpixel, in the normal subpixel. On the other hand, as illustrated in FIG. 10C, the non light-emitting region of the normal subpixel may be formed in an end region, corresponding to an end region closer to the position of the non light-emitting region in the defective subpixel, in the normal subpixel.

### Effects of Present Embodiment

In this way, by providing a non light-emitting region even in a normal subpixel in a defective pixel, the ratio of the sizes of the light-emitting regions of the subpixels can be closer to that in the case of all subpixels being normal subpixels. Here, the light-emitting regions of the subpixels of the defective pixel emit light of mutually different colors. Thus, in the defective pixel, the degradation of white balance can be suppressed.

Furthermore, by determining the size and position of the light-emitting region (non light-emitting region) of the normal subpixel in consideration of the size and position of the light-emitting region (non light-emitting region) of the defective subpixel as described above, white balance can be maintained at a level similar to that of the normal pixel in the defective pixel.

### Example of Realization by Software

Control blocks (in particular, the image analysis unit 309a of the control unit 309) of the defect correction apparatus 300 may be realized by a logic circuit (hardware) formed in an integrated circuit (IC) chip or the like, or may be realized by software using a Central Processing Unit (CPU).

In the case of the latter, the defect correction apparatus 300 is provided with a CPU that executes instructions of a program that is software to realize various functions, a Read Only Memory (ROM) or a storage device (these are referred to as a “storage medium”) in which the above-described program and various data are stored so as to be readable by a computer (or the CPU), a Random Access Memory (RAM) that temporary stores the above-described program, and the like. Then, by the computer (or the CPU) reading out and executing the above-described program from the above-described storage medium, the object of the disclosure is achieved. As the above-described storage medium, a “non-transitory concrete medium,” such as a tape, a disk, a card, a semiconductor memory, or a programmable logic circuit can be used. Furthermore, the above-described program may be supplied to the above-described computer via a chosen transmission medium that can transmit the program (a communication network, broadcast waves, or the like). Note that an aspect of the disclosure can also be realized in the format of data signals that are embedded in carrier waves in which the program is realized by electronic transmission.

### Supplement

According to aspect 1 of the disclosure, a display device (2, 2a) includes a plurality of subpixels (red pixel Pr, green pixel Pg, blue pixel Pb) configured to emit light of different colors. The subpixels include at least one defective subpixel containing foreign matter (conductive foreign matter FB). The at least one defective subpixel includes one region including a non light-emitting region (An) conforming to a planar shape of the foreign matter and the other region including a light-emitting region (Ai). Each of the plurality of subpixels includes a first electrode (anode electrode 22, 22pr, 22pg, 22pb), a light-emitting layer (EL layer 24), and a second electrode (cathode electrode 25) in this order on a substrate (50). The second electrode is provided commonly to the plurality of subpixels. In the at least one defective subpixel, a portion (light emission corresponding portion Ai1), corresponding to the light-emitting region, of the second electrode is not electrically connected with a portion (non light emission corresponding portion An1), corresponding to the non light-emitting region, of the second electrode.

The above configuration can provide a display device in which the above-described two portions of the second electrode are not electrically connected with each other and that has the non light-emitting region conforming to the planar shape of the foreign matter. Thus, a display device in which the defect in the subpixel is precisely corrected can be provided.

According to aspect 2 of the disclosure, in the display device having the configuration of aspect 1, in the at least one defective subpixel, the portion, corresponding to the non light-emitting region, of the second electrode may be surrounded by the portion, corresponding to the light-emitting region, of the second electrode.

With the above configuration, the non light-emitting region can be formed in a configuration in which one defective subpixel contains foreign matter.

According to aspect 3 of the disclosure, in the display device having the configuration of aspect 1, the foreign matter may extend over a plurality of adjacent defective subpixels of the plurality of subpixels, and one portion (defect corresponding portion Ad1) may not be electrically connected with the other portion in the second electrode. The one portion includes the non light-emitting region of each of the plurality of adjacent defective subpixels and a partial region adjacent to the non light-emitting region, the partial region being other than the plurality of adjacent defective subpixels.

With the above configuration, the non light-emitting region can be formed in each of the adjacent defective subpixels in a configuration in which foreign matter extends over the adjacent defective subpixels.

According to aspect 4 of the disclosure, in the display device having the configuration of aspect 1, the foreign matter may extend over a plurality of adjacent defective subpixels of the plurality of subpixel, and in the second electrode, portions corresponding to the non light-emitting regions of the plurality of adjacent defective subpixels may be electrically connected with each other and may not be electrically connected with the other portion.

With the above configuration, the non light-emitting region can be formed in each of the adjacent defective subpixels in a configuration in which foreign matter extends over the adjacent defective subpixels.

According to aspect 5 of the disclosure, in the display device having the configuration of any one of aspects 1 to 4, in a pixel including the at least one defective subpixel, a normal subpixel containing no foreign matter may include one region including a non light-emitting region and the other region including a light-emitting region, and the light-emitting regions of the at least one defective subpixel and the normal subpixel may be configured to emit light of mutually different colors.

With the above configuration, the non light-emitting region is provided even in the normal subpixel in the pixel including the defective subpixel. Thus, the degradation of white balance in the pixel can be suppressed in comparison with a case in which no non light-emitting region is provided in the normal subpixel.

According to aspect 6 of the disclosure, in the display device having the configuration of aspect 5, the ratio of the sizes of the light-emitting regions of the at least one defective subpixel and the normal subpixel may coincide with the ratio of the sizes of the at least one defective subpixel and the normal subpixel.

In a normal pixel, the size or shape of each of the subpixels is determined so that white balance is ensured on the precondition that the entire subpixel is made into a light-emitting region. With the above configuration, the defective subpixel and the normal subpixel are provided with the light-emitting regions having the sizes corresponding to the sizes of the defective subpixel and the normal subpixel. In other words, the light-emitting regions provided in the defective subpixel and the normal subpixel are adjusted in accordance with the size or shape determined as described above. Thus, similar to the normal pixel, white balance can be ensured even in the pixel including the defective subpixel.

According to aspect 7 of the disclosure, in the display device having the configuration of aspect 5 or 6, the light-emitting region may be provided in the normal subpixel while the normal subpixel includes a barycenter of the light-emitting region in a position corresponding to a barycenter position of the light-emitting region in the at least one defective subpixel.

With the above configuration, the light-emitting regions of the subpixels have the same shape or shapes similar to each other. Thus, white balance is readily ensured in the pixel including the defective subpixel.

According to aspect 8 of the disclosure, in the display device having the configuration of aspect 5 or 6, the non light-emitting region of the normal subpixel may be formed in an end region, corresponding to an end region closer to a position of the non light-emitting region in the at least one defective subpixel, in the normal subpixel.

With the above configuration, even in a case where the non light-emitting region of the normal subpixel is positioned in the above-described end region, white balance can be ensured in the pixel including the defective subpixel.

According to aspect 9 of the disclosure, a defect correction apparatus (300) is configured to correct a defect occurring in at least any one of a plurality of subpixels (red pixel Pr, green pixel Pg, blue pixel Pb) included in a display device (2a), the plurality of subpixels being configured to emit light of mutually different colors. The defect correction apparatus includes: a laser light radiation unit (scanner apparatus 303) configured to radiate laser light along an outer periphery of a region containing foreign matter (conductive foreign matter FB) in the at least any one of the plurality of subpixels (defective subpixel) containing the foreign matter in conformance to a shape of the foreign matter contained in the at least any one of the plurality of subpixels, without using a prescribed pattern determined preliminarily.

With the above configuration, by radiating the laser light along the shape of the foreign matter in the subpixel containing the foreign matter, the non light-emitting region can be formed in conformance to the shape of the foreign matter. This can prevent a phenomenon that may occur in defect correction using a predetermined pattern and in which the non light-emitting region increases more than necessary. That is, with the above configuration, the defect in the subpixel can be precisely corrected.

According to aspect 10 of the disclosure, in the defect correction apparatus having the configuration of aspect 9, the laser light radiation unit may be configured to radiate the laser light along the outer periphery while electrically dividing the region containing the foreign matter from the other region of the at least any one of the plurality of subpixels containing the foreign matter.

With the above configuration, in the subpixel containing the foreign matter, only the region containing the foreign matter can be made into a non light-emitting region, and the other region can be made into a light-emitting region. Thus, even the subpixel containing the foreign matter can emit light.

According to aspect 11 of the disclosure, in the defect correction apparatus having the configuration of aspect 9 or 10, in the display device, each of the plurality of subpixels may include a first electrode (anode electrode 22, 22pr, 22pg, and 22pb), a light-emitting layer (EL layer 24), and a second electrode (cathode electrode 25), and the second electrode may be provided commonly to the plurality of subpixels, and the laser light radiation unit may be configured to divide the second electrode into a portion (light emission corresponding portion Ai1) corresponding to a light-emitting region (Ai) and a portion (non light emission corresponding portion An1) corresponding to a non light-emitting region (An) in the at least any one of the plurality of subpixels containing the foreign matter, by radiating the laser light along the outer periphery.

With the above configuration, at least the second electrode is electrically divided into the above-described two portions, and this allows the subpixel containing the foreign matter to emit light.

According to aspect 12 of the disclosure, the defect correction apparatus having the configuration of any one of aspects 9 to 11 may further include an image taking unit (image taking apparatus 308) configured to take an image of the display device, and the laser light radiation unit may be configured to radiate the laser light toward the display device, based on a result of analysis of the image acquired by the image taking unit.

With the above configuration, by analyzing the image acquired by the image taking unit, the foreign matter contained in the display device can be identified. Thus, the laser light can be radiated along the outer periphery of the region containing the foreign matter.

According to aspect 13 of the disclosure, the defect correction apparatus having the configuration of aspect 12 may further include an image analysis unit (309a) configured to determine an irradiation position of the laser light on the display device by identifying a position and a shape of the foreign matter, based on the image acquired by the image taking unit.

With the above configuration, the laser light can be radiated in conformance to various shapes of foreign matter.

According to aspect 14 of the disclosure, in the defect correction apparatus having the configuration of any one of aspects 9 to 13, in a case that the foreign matter extends over a plurality of adjacent subpixels among the plurality of subpixels, the laser light radiation unit may be configured to radiate the laser light along an outer periphery of a portion of the foreign matter, the portion being contained in each of the plurality of adjacent subpixels.

With the above configuration, even in a case where the foreign matter extends over a plurality of adjacent subpixels, the laser light can be radiated so that the region containing the foreign matter is electrically divided from the other region in each of the subpixels.

According to aspect 15 of the disclosure, in the defect correction apparatus having the configuration of aspect 14, the laser light radiation unit may be configured to radiate the laser light along an outer periphery of a defective region (Ad) including a first region and a second region. The first region contains the foreign matter in each of the plurality of adjacent subpixels, and the second region is adjacent to the first region and contains a portion of the foreign matter, the portion being other than the plurality of adjacent subpixels.

With the above configuration, when the foreign matter extends over a plurality of adjacent subpixels, it is ensured that the region containing the foreign matter is made into a non light-emitting region by radiating the laser light as described above.

According to aspect 16 of the disclosure, in the defect correction apparatus having the configuration of aspect 14, the laser light radiation unit may be configured to radiate the laser light along an outer periphery of a defective region (Ad′) containing the entire foreign matter, the entire foreign matter extending over the plurality of adjacent subpixels and a portion other than the plurality of adjacent subpixels.

With the above configuration, when the foreign matter extends over a plurality of adjacent subpixels, it is ensured that the region containing the foreign matter is made into a non light-emitting region by radiating the laser light as described above. Furthermore, the laser light may only be radiated along the outer periphery of the defective region containing the entire foreign matter, so that the laser light irradiation position can be readily determined.

According to aspect 17 of the disclosure, in the defect correction apparatus having the configuration of any one of aspects 9 to 16, the laser light radiation unit may be configured to form a non light-emitting region and a light-emitting region in each of a defective subpixel and a normal subpixel of a pixel including the defective subpixel by radiating the laser light toward a partial region of the normal subpixel. The defective subpixel includes a subpixel containing the foreign matter, and the normal subpixel includes a subpixel containing no foreign matter. The light-emitting regions of the defective subpixel and the normal subpixel may be configured to emit light of mutually different colors.

With the above configuration, the non light-emitting region can be formed in the normal subpixel in the pixel including the defective subpixel. Thus, degradation of white balance in the pixel can be suppressed in comparison with a case in which no non light-emitting region is formed in the normal subpixel.

According to aspect 18 of the disclosure, in the defect correction apparatus having the configuration of aspect 17, the laser light radiation unit may be configured to radiate the laser light toward the normal subpixel with the ratio of the sizes of the light-emitting regions of the defective subpixel and the normal subpixel coinciding with the ratio of the sizes of the defective subpixel and the normal subpixel.

With the above configuration, the light-emitting regions having the sizes corresponding to the sizes of the defective subpixel and the normal subpixel can be formed in the defective subpixel and the normal subpixel. Thus, similar to the normal pixel, white balance can be ensured even in the pixel including the defective subpixel.

According to aspect 19 of the disclosure, in the defect correction apparatus having the configuration of aspect 17 or 18, the laser light radiation unit may be configured to radiate the laser light toward the normal subpixel and to form a light-emitting region in the normal subpixel while the normal subpixel includes a barycenter of the light-emitting region in a position corresponding to a barycenter position of the light-emitting region in the defective subpixel.

With the above configuration, the light-emitting region can be formed in the normal subpixel so that the light-emitting regions of the subpixels have the same shape or shapes similar to each other. Thus, white balance is readily ensured in the pixel including the defective subpixel.

According to aspect 20 of the disclosure, in the defect correction apparatus having the configuration of aspect 17 or 18, the laser light radiation unit may be configured to radiate the laser light toward the normal subpixel while forming the non light-emitting region of the normal subpixel in an end region, corresponding to an end region closer to a position of the non light-emitting region in the defective subpixel, in the normal subpixel.

With the above configuration, the non light-emitting region can be formed in the end region of the normal subpixel. Even in this case, white balance can be ensured in the pixel including the defective subpixel. Furthermore, the non light-emitting region formed in the normal subpixel is positioned in the end region, so that the position does not need to be defined strictly. Thus, the non light-emitting region can be formed in the normal subpixel in a simplified manner.

According to aspect 21 of the disclosure, a display device has a defect to be corrected by the defect correction apparatus according to any one of aspects 9 to 20, and the display device includes: at least any of an organic light emitting diode, an inorganic light emitting diode, and a quantum dot light emitting diode.

With the above configuration, unlike a display device using liquid crystal, the laser light is radiated only along the outer periphery of a region containing foreign matter instead of the entire region, thereby making the region other than the aforementioned region into a light-emitting region in a subpixel containing the foreign matter.

According to aspect 22 of the disclosure, a manufacturing apparatus (100) is configured to manufacture a display device (2), and the manufacturing apparatus includes the defect correction apparatus according to any one of aspects 9 to 20.

With the above configuration, a display device in which a defect in a subpixel is precisely corrected can be manufactured.

A defect correction method according to aspect 23 of the disclosure is a defect correction method for correcting a defect occurring in at least any one of a plurality of subpixels included in a display device, the plurality of subpixels being configured to emit light of mutually different colors. The defect correction method includes radiating laser light along an outer periphery of a region containing foreign matter in the at least any one of the plurality of subpixels containing the foreign matter in conformance to a shape of the foreign matter contained in the at least any one of the plurality of subpixels, without using a prescribed pattern determined preliminarily.

With the above method, the same effects can be achieved as of aspect 1.

### ADDITIONAL ITEMS

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

2, 2a Display device
22, 22pr, 22pg, 22pb Anode electrode (first electrode)
24 EL layer (light-emitting layer)
25 Cathode electrode (second electrode)
50 Substrate
100 Manufacturing apparatus
300 Defect correction apparatus
303 Scanner apparatus (laser light radiation unit)
308 Image taking apparatus (image taking unit)
309a Image analysis unit
Ad, Ad′ Defective region
Ad1 Defect corresponding portion (portion including non light-emitting region of defective subpixel and partial region adjacent to non light-emitting region and other than defective subpixel)
Ai Light-emitting region
Ai1 Light emission corresponding portion (portion, corresponding to light-emitting region, of second electrode)
An Non light-emitting region
An1 Non light emission corresponding portion (portion, corresponding to non light-emitting region, of second electrode)
Pr Red pixel (subpixel, defective subpixel, normal subpixel)
Pg Green pixel (subpixel, defective subpixel, normal subpixel)
Pb Blue pixel (subpixel, defective subpixel, normal subpixel)
FB Conductive foreign matter (foreign matter)

1-4. (canceled)

5. A display device comprising:
a plurality of subpixels configured to emit light of mutually different colors,
wherein the plurality of subpixels include at least one defective subpixel containing foreign matter,
the at least one defective subpixel includes
one region including a non light-emitting region conforming to a planar shape of the foreign matter, and
the other region including a light-emitting region,
each of the plurality of subpixels includes
a substrate, and
a first electrode, a light-emitting layer, and a second electrode in this order on the substrate,
the second electrode is provided commonly to the plurality of subpixels,
in the at least one defective subpixel, a portion, corresponding to the light-emitting region, of the second electrode is not electrically connected with a portion, corresponding to the non light-emitting region, of the second electrode,
in a pixel including the at least one defective subpixel, a normal subpixel containing no foreign matter includes one region including a non light-emitting region and the other region including a light-emitting region, and
the light-emitting regions of the at least one defective subpixel and the normal subpixel are configured to emit light of mutually different colors.

6. The display device according to claim 5,
wherein a ratio of sizes of the light-emitting regions of the at least one defective subpixel and the normal subpixel coincides with a ratio of sizes of the at least one defective subpixel and the normal subpixel.

7. The display device according to claim 5,
wherein the light-emitting region is provided in the normal subpixel while the normal subpixel includes a barycenter of the light-emitting region in a position corresponding to a barycenter position of the light-emitting region in the at least one defective subpixel.

8. The display device according to claim 5,
wherein the non light-emitting region of the normal subpixel is formed in an end region, corresponding to an end region closer to a position of the non light-emitting region in the at least one defective subpixel, in the normal subpixel.

9-16. (canceled)

17. A defect correction apparatus configured to correct a defect occurring in at least any one of a plurality of subpixels included in a display device, the plurality of subpixels being configured to emit light of mutually different colors, the defect correction apparatus comprising:
a laser light radiation unit configured to radiate laser light along an outer periphery of a region containing foreign matter in the at least any one of the plurality of subpixels containing the foreign matter in conformance to a shape of the foreign matter contained in the at least any one of the plurality of subpixels, without using a prescribed pattern determined preliminarily,
wherein the laser light radiation unit is configured to form a non light-emitting region and a light-emitting region in each of a defective subpixel and a normal subpixel of a pixel including the defective subpixel by radiating the laser light toward a partial region of the normal subpixel, the defective subpixel including a subpixel containing the foreign matter, the normal subpixel including a subpixel containing no foreign matter, and
the light-emitting regions of the defective subpixel and the normal subpixel are configured to emit light of mutually different colors.

18. The defect correction apparatus according to claim 17,
wherein the laser light radiation unit is configured to radiate the laser light toward the normal subpixel with a ratio of sizes of the light-emitting regions of the defective subpixel and the normal subpixel coinciding with a ratio of sizes of the defective subpixel and the normal subpixel.

19. The defect correction apparatus according to claim 17,
wherein the laser light radiation unit is configured to radiate the laser light toward the normal subpixel and to form a light-emitting region in the normal subpixel while the normal subpixel includes a barycenter of the light-emitting region in a position corresponding to a barycenter position of the light-emitting region in the defective subpixel.

20. The defect correction apparatus according to claim 17,
wherein the laser light radiation unit is configured to radiate the laser light toward the normal subpixel while forming the non light-emitting region of the normal subpixel in an end region, corresponding to an end region closer to a position of the non light-emitting region in the defective subpixel, in the normal subpixel.

21. A display device including a defect to be corrected by the defect correction apparatus according to claim 17, the display device comprising:
at least any of an organic light emitting diode, an inorganic light emitting diode, and a quantum dot light emitting diode.

22. A manufacturing apparatus configured to manufacture a display device, the manufacturing apparatus comprising:
the defect correction apparatus according to claim 17.

23. (canceled)

24. The display device according to claim 5,
wherein, in the at least one defective subpixel, the portion, corresponding to the non light-emitting region, of the second electrode is surrounded by the portion, corresponding to the light-emitting region, of the second electrode.

25. The display device according to claim 5,
wherein the at least one defective subpixel includes a plurality of adjacent defective subpixels,
the foreign matter extends over the plurality of adjacent defective subpixels, and
one portion is not electrically connected with other portion in the second electrode, the one portion including the non light-emitting region of each of the plurality of adjacent defective subpixels and a partial region adjacent to the non light-emitting region, the partial region being other than the plurality of adjacent defective subpixels.

26. The display device according to claim 5,
wherein the at least one defective subpixel includes a plurality of adjacent defective subpixels,
the foreign matter extends over the plurality of adjacent defective subpixels, and
in the second electrode, portions corresponding to the non light-emitting regions of the plurality of adjacent defective subpixels are electrically connected with each other and are not electrically connected with other portion.

27. The defect correction apparatus according to claim 17,
wherein the laser light radiation unit is configured to radiate the laser light along the outer periphery while electrically dividing the region containing the foreign matter from the other region of the at least any one of the plurality of subpixels containing the foreign matter.

28. The defect correction apparatus according to claim 17,
wherein, in the display device, each of the plurality of subpixels includes a first electrode, a light-emitting layer, and a second electrode, the second electrode being provided commonly to the plurality of subpixels, and
the laser light radiation unit is configured to electrically divide the second electrode into a portion corresponding to a light-emitting region and a portion corresponding to a non light-emitting region in the at least any one of the plurality of subpixels containing the foreign matter, by radiating the laser light along the outer periphery.

29. The defect correction apparatus according to claim 17 further comprising:
an image taking unit configured to take an image of the display device,
wherein the laser light radiation unit is configured to radiate the laser light toward the display device, based on a result of analysis of the image acquired by the image taking unit.

30. The defect correction apparatus according to claim 17 further comprising:
an image analysis unit configured to determine an irradiation position of the laser light on the display device by identifying a position and a shape of the foreign matter, based on the image acquired by the image taking unit.

31. The defect correction apparatus according to claim 17,
wherein, in a case that the foreign matter extends over a plurality of adjacent subpixels among the plurality of subpixels, the laser light radiation unit is configured to radiate the laser light along an outer periphery of a portion of the foreign matter, the portion being contained in each of the plurality of adjacent subpixels.

32. The defect correction apparatus according to claim 17,
wherein the laser light radiation unit is configured to radiate the laser light along an outer periphery of a defective region including a first region and a second region, wherein
the first region contains the foreign matter in each of the plurality of adjacent subpixels, and
the second region is adjacent to the first region and contains a portion of the foreign matter, the portion being other than the plurality of adjacent subpixels.

33. The defect correction apparatus according to claim 17,
wherein the laser light radiation unit is configured to radiate the laser light along an outer periphery of a defective region containing the entire foreign matter, the entire foreign matter extending over the plurality of adjacent subpixels and a portion other than the plurality of adjacent subpixels.
